(19) United States
(12) Patent Application Publication
(10) Pub. No.: US 2023/0300980 A1
(43) Pub. Date: Sep. 21, 2023

(54) NON-IMMERSIVE DRY SINTERING STRATEGY FOR REALIZING DECENT METAL BASED ELECTRODES

(71) Applicant: THE UNIVERSITY OF HONG KONG, Hong Kong (CN)

(72) Inventors: Chik Ho Choy, Hong Kong (HK); Xinjun He, Hong Kong (HK)

(21) Appl. No.: 18/014,760

(22) PCT Filed: Jul. 9, 2021
(86) PCT No.: PCT/CN2021/105466

§ 371 Date: Jan. 6, 2023

Related U.S. Application Data
(60) Provisional application No. 63/049,655, filed on Jul. 9, 2020.

(51) Int. Cl. H05K 1/09; H01L 31/0224

(52) U.S. Cl. CPC H05K 1/097; H01L 31/022425; H01L 31/022491; H05K 2201/10143; H05K 2203/1131

(57) ABSTRACT

Disclosed are methods of sintering metal nanoparticles and methods of making conductive metal films.

This international patent application claims the benefit of U.S. Provisional Pat. Application No. 63/049,655 filed on Jul. 9, 2020, the entire content of which is incorporated by reference for all purpose.

### TECHNICAL FIELD

Disclosed are methods of sintering metal nanoparticles and methods of making conductive metal films.

### BACKGROUND

A lot of work has been devoted to developing solution-processed electrodes such as silver nanowires (Ag NWs). However, the development of the fully solution-processed device has been far behind the evaporated electrode counterpart. For example in OSC devices, the power conversion efficiency (PCE) of fully solution-processed device has only achieved 11.9%, which is far behind 15.2% of its evaporated counterpart.

### SUMMARY

The following presents a simplified summary of the invention in order to provide a basic understanding of some aspects of the invention. This summary is not an extensive overview of the invention. It is intended to neither identify key or critical elements of the invention nor delineate the scope of the invention. Rather, the sole purpose of this summary is to present some concepts of the invention in a simplified form as a prelude to the more detailed description that is presented hereinafter.

Disclosed herein are methods of sintering of isolated metal nanoparticles into a smooth and highly conductive metal film involving depositing a layer of metal nanoparticles; depositing the dry sintering layer; and optionally after some time, drying the sintered metal film.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF SUMMARY OF THE DRAWINGS

The patent or application file contains at least one drawing executed in color. Copies of this patent or patent application publication with color drawing(s) will be provided by the Office upon request and payment of the necessary fee.

FIG. 1 generally depicts cross-sectional scanning electron microscopy of organic solar cells with different solution processed electrodes deposited on top. FIG. 1(a) shows a control device without top electrode, FIG. 1(b) shows commercial silver paste #1 (CAIG (CW-200B)), FIG. 1(c) shows commercial silver paste #2 (HumiSeal (948-06G)), FIG. 1(d) shows commercial colloidal graphite (TED PELLA, Inc. (CAT#16053)), and FIG. 1(e) shows synthesized silver nanowires and (f) non-immersive sintered electrode (the inventive approach).

FIGS. 2(a-f) show Ex-situ SEM images of Ag NPs film under different sintering times. FIG. 2(g) shows sheet resistance of the electrode after sintering from 0 to 1 hour. Transmission electron microscopy (TEM) images of Ag NPs FIG. 2(h) before and FIG. 2(i) after sintering. FIG. 2(j) shows core-level Ag 3d X-ray photoelectron spectroscopy (XPS) spectra of the electrode in pristine and sintered states. FIG. 2(k) shows the extracted electrodes surface height histogram figure from atomic force microscopy (AFM). FIG. 2(l) shows core-level Mo 3d XPS spectra derived from different surfaces (A for HMO surface, B for Ag surface as shown in the inset illustration. Both of the samples have been annealed at 65° C. for 10 min).

FIG. 3(a) shows the sheet resistance of PEDOT:PSS and PMA based electrode. FIG. 3(b) shows the thickness of the PEDOT:PSS/Ag. FIG. 3(c) shows an SEM and FIG. 3(d) shows AFM images of Ag electrode sintered by PEDOT:PSS layer.

FIG. 4(a) is a cross-sectional SEM image of the fabricated OSCs. FIG. 4(b) is a transmittance spectrum of the OSC. The inset shows the photo of the semi-transparent device. FIG. 4(c) shows the absorption spectrum of the organic active layer and the reflection spectrum of the sintered electrode. FIG. 4(d) is ToF-SIMS of the evaporation-free device. FIG. 4(e) is TPC measurement, FIG. 4(f) shows J-V curves, and FIG. 4(g) shows stabilized photocurrent of the OSCs with an evaporated or solution processed top electrode. FIG. 4(h) shows the PCE comparison of OSCs between this work and other works with a solution processed top electrode (The corresponding active layer materials information are provided. Those not specified are PC₆₁BM or PC₇₁BM based OSCs).

### DETAILED DESCRIPTION

Solution-processed optoelectronics such as solar cells (SCs), light emitting diodes (LEDs) and sensors have drawn tremendous attention in recent years due to their interesting features of low- cost, simple, green and easily scalable. To realize the ultimate goal of fully solution process in fabrication, it is highly desirable to form metal back electrodes by solution process instead of high-vacuum evaporation. However, the complex solvents used in typical metal precursor solution and the post-treatment required such as high-temperature annealing will easily damage functional layers and degrade device performance such as organic SCs (OSCs), organic LEDs and etc.

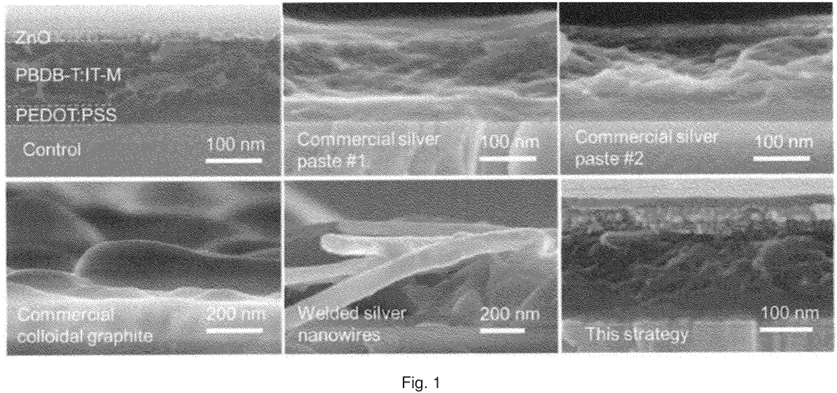

One of the biggest challenges that hinders the development of top solution-processed electrode lies in the interfacial contact. In comparison with evaporation deposition which stacking materials without permeating to other layers of the device, solution process usually involves electrode deposition, pre or post treatment on the film. Unfortunately, the detrimental chemicals and solvents, mechanical force or high temperature annealing involved in these processes will exert on the whole device, which will easily cause materials dissolution, corrosion or poor inter-layer contact and fail the device. As an example, FIG. 1 presents the cross-sectional scanning electron microscopy (SEM) image of OSCs fabricated with different solution-processed top electrodes including commercial silver pastes, graphite and synthesized Ag NWs. It shows that the functional layers in OSCs have been dissolved or partially penetrated by the solution-processed electrodes. It is urgent to solve those problems in order to construct scalable and high-performance multilayer devices including OSCs, OLEDs, detectors, etc.

Three typical solution-processed electrodes have been reported including carbon electrode, conductive polymer electrode and metal electrode. Carbon materials such as graphene and carbon nanotubes often suffer from high resistance because of the low intrinsic carrier concentration or low inter-tube contact. Conductive polymers such as PEDOT:PSS have been extensively studied as electrode in OSCs because of its flexibility, conductivity and so on. However, water is often used in the precursor solution, which results in terrible wetting issue when deposited on hydrophobic organic active layer. In addition, there are concerns about its strong light absorption, which will impede device performance.

Metal electrodes, e.g. silver nanowire and silver paste are attractive benefitting from their excellent conductivity and ductility. For instance, silver nanowire based electrode with a low sheet resistance of 13 ohm/sq was obtained after the removal of PVP ligand. It is essential to conduct post-treatment to form highly conductive metal electrode. Treatments include thermal annealing, light induced sintering, and chemical sintering have been reported to sinter or weld individual metal media to form an interconnecting and conductive network However, those post-treatments will easily destroy the underlying functional layers in the multilayer devices and cause device failure.

To get rid of the post-treatment effect and the detrimental solvents existed in the metal precursor solution, lamination or transformation process have been extensively applied. However, it is well-known that lamination process has poor device reproducibility. Critically, the interfacial contact between the top and bottom devices shall be addressed after lamination to improve the carrier transportation properties and device efficiency.

Another concern of the typical transparent solution-processed electrode is the absorption loss compared to evaporated electrode due to the sacrifice of the second light pass particularly in the fabrication of high-efficiency OSCs that possess strong absorption in the red to near infrared region. As a result, the corresponding often suffers from lower short-circuit current (Jsc). For example, Fan and co-workers have fabricated fully solution-solution processed OSCs employing a modified PEDOT:PSS as top cathode. The device exhibited a PCE of 11.12%, which is lower than 13.42% of its evaporated counterpart. The major difference comes from the Jsc (19.55 mA cm² and 22.66 mA cm² for solution process and evaporation, respectively). Therefore, it is challenging to realize solution-processed top electrode that enables good interfacial contact with the carrier transport layer (CTL), negligible influence on other layers of multi-layered device and ensures sufficient light absorption of the active layer.

Described herein is a non-immersive sintering approach (NIS) to sinter Ag NPs film by depositing a dry layer of material that can provide hydrogen ions such as hydrogen-intercalated molybdenum oxide (HMO), hydrogen-intercalated vanadium oxide (HVO), PEDOT:PSS, phosphomolybdic acid (PMA) and etc., to address the challenges:

1. Easy process: Only two steps are involved including metal nanoparticles deposition and dry sintering layer deposition. (Here, we employ HMO as a demonstration). Sintering the isolated nanoparticles is a simple and robust approach, due to the solution process regardless the surface roughness.

2. Excellent film quality: Root mean squire (RMS) roughness of the sintered film achieves 2.313 nm, lower than the evaporated Ag electrode (2.767 nm), which suggests its excellent film morphology. An impressively low sheet resistance of 8.6 Ω/sq is obtained, indicating an excellent charge transportation efficiency.

3. Excluding the detrimental chemicals, solvents, pre and post-treatment during top electrode deposition. The aforementioned sintering materials can effectively sinter the Ag NPs as a dry film, whereas other methods require the metal electrode to immerse into certain solution to ensure effective welding or soldering. The dry sintering feature of this approach minimizes the solvent penetration to the underlying layers. In addition, the employed sintering material (Mo) has no clear diffusion to the bottom layers. These two features enable a negligible influence on the whole device during electrode deposition process. Therefore, the properties of the bottom layers such as light absorption and charge extraction have been well preserved.

4. Good optical reflection in near infrared region: The sintered electrode shows good light reflection (>70%) in the red to near infrared region. This is of great essence especially in the fabrication high-efficiency OSCs in which the non-fullerene acceptors have strong absorption in the near infrared range and contribute to the overall device efficiency.

5. Environmental friendly process: room-temperature process, no toxic raw material or product is required or generated.

6. Compatible to large-scale manufacturing such as roll-to-roll coating, Mayer rod coating, inkjet printing and spray coating.

7. High material utility.

8. Low energy consumption in production: no requirement of high temperature, high vacuum and large current in the process. The process for forming the smooth and highly conductive metal film is a low-cost approach, which involves simple equipment, cheap materials and low power consumption process.

This invention of non-immersive dry sintering strategy resolves the below problems for top electrode deposition.

First, the new approach described herein eliminates the detrimental solvents (e.g. those in silver paste) or post-treatments such as thermal annealing that will easily permeate or exert on multilayer devices to cause destruction or poor inter-layer contact during the solution-processed top electrodes deposition.

The new solution-processed electrode is achieved through a dry sintering process that effectively connect the isolated Ag NPs through a dry layer. It is not required to immerse the device into any solution, which minimizes the solvent penetration and decreases the possibility of material dissolution encountered by many conventional sintering, welding or soldering approaches. In addition, the employed MoO₃ framework has not diffused to the underlying layers. These features ensure a negligible influence on the underlying functional layers and the device is well preserved after the electrode deposition process.

Second, the typical transparent top electrodes such as Ag NWs, PEDOT:PSS and graphene have sacrificed the second light pass compared to evaporated metal electrode, which limits the absorption of some light harvesting devices such as OSCs. Therefore, the fabricated evaporation-free devices often suffer from worse performance compared to its evaporated counterpart.

The applied HMO can effectively sinter the Ag NPs and produce a conductive and smooth film with continuous crystal lattice. The achieved highly conductive film (8.6 Ω/sq) enables an efficient inner or inter-layer charge transportation. Additionally, the sintered Ag electrode presented a small root mean squire (RMS) roughness of 2.313 nm. A smooth and connected Ag film is essential to high light reflection in the near infrared range (>70%) and it contributes to an efficient light absorption of light harvesting devices.

For a thick layer of silver nanoparticles (for example thicker than 1 µm), in some instances it can be difficult for the solution to penetrate and the sintering time shall be increased accordingly. However, the typical thickness of regular electrode is less than 1 µm, such as 100 nm.

The electrode deposition process is finished by dynamic coating of Ag NPs film and HMO layer with HMO either on top (i.e., Ag NPs/HMO) or at bottom (i.e., HMO/Ag NPs). We will firstly show the electrode properties where Ag NPs are directly coated on top of dry HMO to monitor the morphology evolution. For device fabrication, the HMO is coated on top of Ag NPs to sinter the electrode while not permeate to underlying layers.

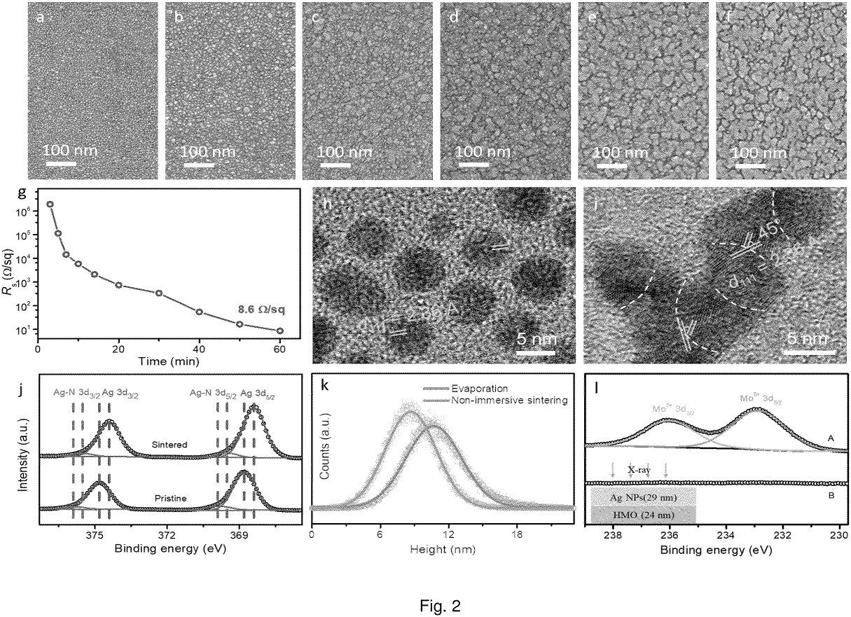

FIGS. 2a-f show the ex-situ SEM images of Ag NPs electrode after sintering of different times (0-1 hour). It is worthy to note that the sintering time is related to the layer thickness of the Ag NPs and HMO. Thicker Ag NPs and thinner HMO usually requires longer time to fully sinter the electrode. An instant sintering can be realized for 24-nm HMO and 29-nm Ag NPs. To demonstrate the morphological evolution during sintering, we deposit 10-nm HMO and 29-nm Ag NPs to prolong the sintering process. At the beginning, the Ag NPs remain their isolated morphology (FIG. 2a). With time goes by, the particles start to merge together and the particle size shows an obvious increase. Finally after one hour, the connected Ag continents with size around 100 nm are produced (FIG. 2f). The sheet resistance shows a dramatic decrease from over 10⁶ to 8.6 Ω/sq, which is much lower than that of a typical indium tin oxide (ITO) electrode (~15 Ω/sq). The low sheet resistance originates from the good inter-particle crystal lattice matching in the sintered electrode. Before sintering, crystal lattice distance of 2.36 Å (angstrom) are characterized for the isolated nanoparticles, which can be assigned to the (111) plane of cubic silver (FIG. 2h). FIG. 2i presents the transmission electron microscopy (TEM) image of the sintered Ag NPs with the white dashed lines marking the interface between NPs. The particles are not chaotically stacked together after sintering, they are following a certain crystal orientation (45°). These features contribute to the very low sheet resistance of the thin Ag NPs electrode. Atomic force microscopy (AFM) are applied to characterize the film flatness (FIG. 2k). The sintered film presents a low root mean square (RMS) roughness of 2.313 nm, which is smoother than 2.767 nm of an evaporated Ag electrode.

FIG. 2j presents the core-level Ag 3d XPS spectra of the electrode in pristine and sintered state. In sintered state, the spectrum can be deconvoluted into four peaks. Two major peaks at 374.4 and 368.4 eV can be well indexed to Ag⁰ 3d_{3/2} and Ag⁰ 3d_{5/2} of bulk silver. The other two peaks located 375.5 and 369.5 eV can be assigned to nitrogen coordinated silver (Ag-N 3d_{3/2} and Ag-N 3d_{5/2}). The corresponding peaks in pristine electrode shift to higher binding energy (0.4 eV) due to the depletion of electrons in valence band with the decreasing particle size. This result further confirms the Ag NPs are well sintered into connected bulk silver. Simultaneously, the Ag-N/Ag ratio declines from 10.83% to 6.97% after sintering. Since we employ oleylamine as the nanoparticle-capping agent, the obvious decrease suggests a breakage of the Ag-N coordinate bond, which is essential to the sintering process. FIG. 2l exhibits the core-level Mo 3d spectra derived from HMO surface (A) or sintered Ag NPs surface (as shown in the inset illustration picture, B).

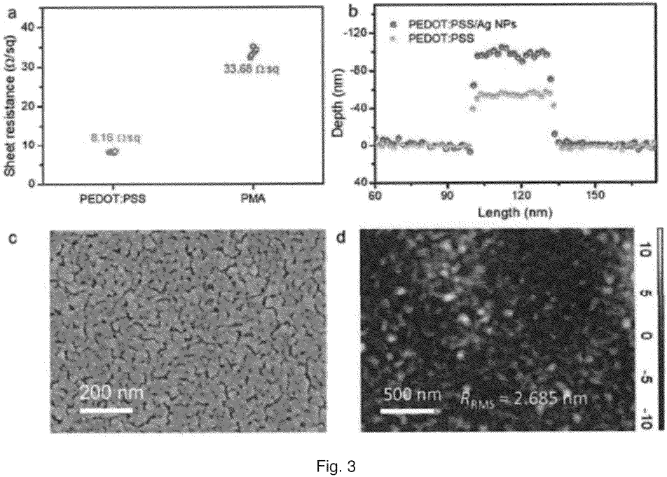

No obvious Mo signal is detected on the top surface of Ag NPs, which implies Mo has not permeated through Ag NPs. Therefore, we concluded the non-immersive sintering mechanism as following. After spin-coating of two layers (Ag NPs and HMO layer), the Ag-N coordinate bond will be broken. Afterwards, the exposed Ag NPs will merge and connect to each other, leading to a slight mismatch of the (111) crystal plane between different particles. Such intrinsic inter-particle connection ensures low sheet resistance and provides excellent charge transportation efficiency. Importantly, the dry sintering strategy is also effective if we replace the HMO with other materials that can provide H+. To verify it, we deposited Ag NPs on Poly(3,4-ethylenedioxythiophene):polystyrene sulfonate (PEDOT:PSS) and phosphomolybdic acid (PMA). As shown in FIG. 3a, the sheet resistance of both films show drastic decrease from insolation to 8.16 and 33.68 Ω/sq of PEDOT:PSS and PMA, respectively. A 55 nm PEDOT:PSS can effectively sinter 40 nm Ag NPs (FIGS. 3b, c) and result in a smooth film (R_{RMS} = 2.685 nm, FIG. 3d).

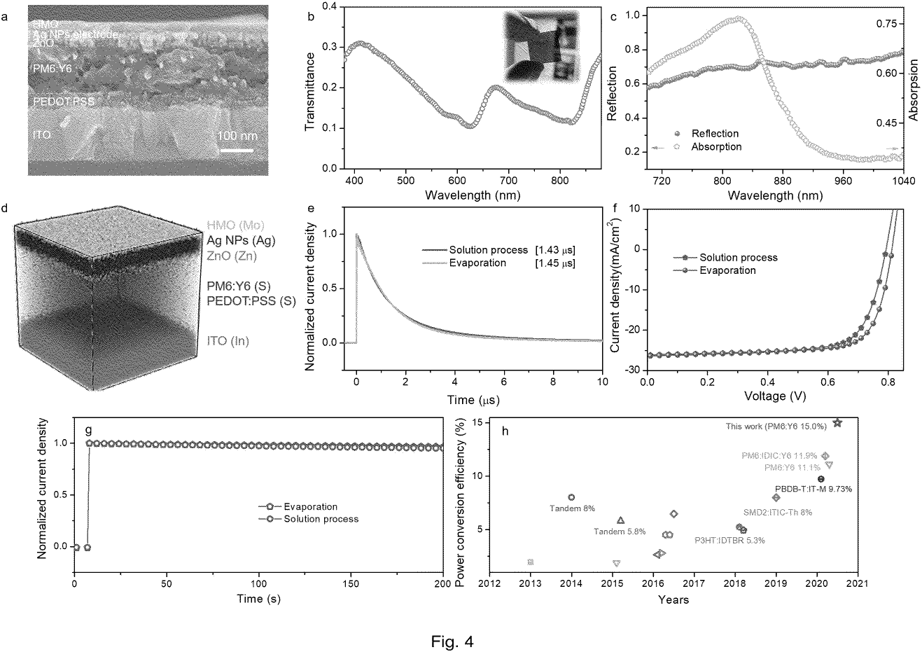

To demonstrate the performance of the top electrode, we applied this strategy to fabri cate high- efficiency OSCs with a device configuration of ITO/PEDOT:PSS/Poly[(2,6-(4,8-b is(5-(2-ethylhexyl-3-fluoro)thiophen-2-yl)-benzo[1,2-b:4,5-b′]dithiophene))-alt-(5,5-(1’,3′-di-2-thienyl-5’,7′-bis(2-ethylhexyl)benzo[1’,2′-c:4’,5’ -c′]dithiophene-4,8-dione)]:2,2′-((2Z,2′Z)-((12,13-bis(2-ethylhexyl)-3,9-diundecyl-12,13-dihydro-[1,2,5]thiadiazolo[3,4-e]thieno[2”,3”: 4’,5’]thieno[2’,3’:4,5]pyrrolo[3,2-g]thieno[2’,3’:4,5]thieno[3,2-b]indole-2,10-diyl)bis(methan ylylid-ene))bis(5,6-difluoro-3-oxo-2,3-dihydro-1H-indene-2,1-diylidene))dimalono-nitrile (P M6:Y6)/ZnO/Ag NPs/HMO. As shown in the cross-sectional SEM image (FIG. 4a), the A g NPs are well sintered into a connected film with the HMO decently stacked atop. More im portantly, the device preserved its clear and hierarchical structure after the deposition of top electrode. The photograph of the fabricated semi-transparent device and its transmittance spe ctrum is provided in FIG. 4b. Despite two strong absorption regions correlated to the active donor and acceptor, the device transmittance is still over 20% in the visible range (380-740 nm), which is higher than many reported semi-transparent devices [Energy & Environmental Science, 2018, 11, 2225-2234; Advanced Science 2016, 3, 1500342; ACS Applied Material s Interfaces 2018, 10, 943-954]. Another unique and important feature of our sintered Ag NP s electrode is that it offers 70% light reflection in the red to near infrared region (700-1050 n m), which is highly overlapped with the absorption range of the non-fullerene acceptor such as Y6 as shown in FIG. 4c. It is well- known that devices with transparent top electrode su ch as graphene, PEDOT:PSS and silver nanowires have to sacrifice the second pass of the lig ht, which leads to a lower light absorption and short-circuit current (Jsc). In contrast, the hig h reflection of this sintered Ag NPs electrode particularly in the infrared range successfully o vercome this shortcoming. In other words, semi- transparent device with this Ag NPs electro de can simultaneously achieve a good device transparency and sufficient light absorption.

For the fabrication of fully solution-processed devices, it is essential to make sure that the top electrode deposition process has negligible influence on the other layers. Therefore, we implement time-of-flight secondary ion mass spectrometry (ToF-SIMS) on the device to characterize the vertical elements distribution. As shown in FIG. 4d, the elements from different layers exhibit a decent hierarchical distribution that can be well indexed to the device configuration. Notably, Mo element is only present at the top layer. This result is in consistent with the core-level Mo 3d XPS in FIG. 2l and suggests that the main framework of HMO (MoO₃) has not diffused to the underlying layers to affect the performance of the devices. In addition, we have further conducted transient photocurrent measurement to study the influence of the NIS process on the charge extraction properties of the devices (FIG. 4e). The fully solution-processed device exhibits charge extraction time of 1.43 µs, which is similar to its evaporated counterpart (1.45 µs) and also confirms the bottom functional layers are preserved in the NIS process. As a result, the fully solution-processed OSCs delivers a PCE of 15.0% with a Jsc of 26.19 mA cm⁻², open circuit voltage (Voc) of 0.79 V and fill factor (FF) of 0.725, which is comparable to the evaporated device (with 100 nm evaporated Ag electrode) with a PCE of 15.8%, Jsc of 26.41 mA cm⁻², Voc of 0.81 V and FF of 0.739 (FIG. 4f). Notably, the comparable Jsc of the NIS device is ascribed to the high reflection in the infrared range and efficient charge extraction. Importantly, the stabilized photocurrent at the maximum power point of the devices with a solution-processed and evaporated top electrode is almost overlapped (FIG. 4g). The NIS devices are very stable, it remains 95% of its original efficiency after continuous working at the maximum power point for 300 s. As shown in FIG. 4h, the PCE of our solution-processed device outperforms all of the reported devices with a solution-processed top electrode including PEDOT:PSS, Ag NWs, Ag NPs/inks, Ag pastes, and graphene.

The detailed process of non-immersive sintering strategy: take HMO as an example. Firstly, a layer of silver nanoparticles was deposited (spin-coating, spray coating, inkjet printing, slot-die coating or any other coating method) on substrate (polymer, glass or any other film surface) with a thickness of 29 nm. Then, the synthesized hydrogen intercalated molybdenum oxide was deposited with a thickness of 24 nm. The sintering is effective whether the Ag NPs on top or at the bottom of HMO layer. The sintering can be instantly achieved with the aforementioned thickness combination. After the deposition, the film was heated at mild temperature (e.g. 65° C.) for 10 minutes to drive away the small amount solvent left in the film.

It is important to note that described herein is not merely the Ag NPs, but the new class of solution-processed top electrode though the dry sintering process.

Nowadays, thermal evaporation of metal back electrode is most prevailing method in the market or field. However, when it comes to the large-scale production, the high energy consumption and low material (noble metal) utility can be an obstacle. The demand for solution-processed metal electrode that has negligible influence on the underlying layers and satisfy the strong absorption of the high-efficiency solar cells devices will increase in the near future.

Unless otherwise indicated in the examples and elsewhere in the specification and claims, all parts and percentages are by weight, all temperatures are in degrees Centigrade, and pressure is at or near atmospheric pressure.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

While the invention is explained in relation to certain embodiments, it is to be understood that various modifications thereof will become apparent to those skilled in the art upon reading the specification. Therefore, it is to be understood that the invention disclosed herein is intended to cover such modifications as fall within the scope of the appended claims.

What is claimed is:

1. A method of preparing a conductive metal film, comprising:
depositing a layer of metal nanoparticles, wherein the metal nanoparticles are isolated in the layer;
depositing a dry sintering layer;
sintering the layer of metal nanoparticles to form a sintered metal film; and
optionally drying the sintered metal film.

2. The method of claim 1, wherein a deposition sequence comprises:
depositing the dry sintering layer; and then depositing the layer of metal nanoparticles on the dry sintering layer, or
depositing the layer of metal nanoparticles, and then depositing the dry sintering layer on the layer of metal nanoparticles.

3. A method of sintering of isolated metal nanoparticles into a smooth and conductive metal film, comprising:
depositing a layer of metal nanoparticles;
depositing the dry sintering layer; and
optionally after some time, drying the sintered metal film.

4. The method of claim 3, a deposition sequence comprises:
depositing the dry sintering layer; and then depositing the layer of metal nanoparticles.

5. The method of claim 1, wherein said metal nanoparticles comprise nanocubes, nanosphere, and nanoparticles in any other shapes.

6. The method of claim 1, wherein said metal comprises one or more of Ag, Cu, and Au.

7. The method of claim 1, wherein said dry sintering layer comprise materials that provide hydrogen ions such as hydrogen-intercalated molybdenum oxide (HMO), hydrogen-intercalated vanadium oxide (HVO), PEDOT:PSS, or phosphomolybdic acid (PMA), which is dry and has no obvious solution after deposition.

8. The method of claim 1, wherein said dry sintering is performed when both layers are wet with liquid and particularly both layers are dry or in solid state without any liquid or solution attached on the layers, and wherein the dry state or solid state is achieved when almost all of the solvent in the layers is gone during or after deposition.

9. The method of claim 1, wherein the method comprises depositing the layer of metal nanoparticles on a substrate, or depositing the dry sintering layer on a substrate, and said substrate comprises one or more of the common substrates, such as bare glass, silicon wafer, metal film, polymer or flexible substrate, and device surfaces.

10. The method of claim 1, wherein the deposit of the layer of metal nanoparticles comprises:
depositing metal nanoparticles solution on a substrate; wherein a solvent for dispersing metal nanoparticles can be one of the common solvents, such as hexane, octane, and toluene, and said metal nanoparticles deposition approach can be one of the common approaches, such as spin-coating, drop-casting, spray-coating, inkjet or screen printing, Mayer rod coating, and doctor blade coating techniques.

11. The method of claim 1, wherein the deposit of the layer of dry sintering layer comprises:
depositing the dry sintering layer comprising a sintering material on a substrate; wherein said deposition approach can be one of the common approaches, such as spin-coating, drop-casting, spray-coating, inkjet or screen printing, Mayer rod coating, and doctor blade techniques, which ensures the resultant film is dry and there is no obvious solution after deposition; wherein the solvent for dispersing the sintering materials can be one of the common solvents, such as methanol, ethanol, 1-butanol, isopropanol, 1-butanol, DMF, ethyl acetate, and anisole.

12. The method of claim 1, wherein said drying can be accomplished by any methods such as vacuum drying, oven or hot plate drying, and natural volatilization.

13. The method of claim 1, wherein drying the sintered metal film is performed after some time after the sintered metal film is formed, said some time depends on the relative thickness of the metal film and the dry sintering layer, and for a 24 nm hydrogen-intercalated molybdenum oxide film and 29 nm silver nanoparticles film, the nanoparticles can be instantly sintered without waiting (0 s) after the deposition process.

14. The method of claim 1, wherein the process for forming said conductive metal film is an environmentally friendly process, which is carried out in air and mainly at room temperature, and no toxic chemical and by-product are required or produced during the process.

15. The method of claim 1, wherein the electrical conductivity of said conductive metal film is dramatically increased as compared to the as-deposited metal nanoparticle film.

16. The method of claim 1, wherein said conductive metal film has the advantages over conventionally thermal evaporated metal film, particularly in terms of the cost and time consumption.

17. A conductive metal film obtained by the method of claim 1.

18. The conductive metal film of claim 17, wherein it has a light reflection of greater than 70% in the red to near infrared region.

19. The conductive metal film of claim 17, wherein it has a sheet resistance of lower than 500 Ω/sq.

20. The conductive metal film of claim 17, wherein it has a root mean square (RMS) roughness of lower than 20 nm.

21. A solar cell, organic light emitting device, liquid crystal display, or thin-film transistor comprising the conductive metal film made according to claim 17.
